(19) United States
(12) Patent Application Publication
(10) Pub. No.: US 2021/0005717 A1
(43) Pub. Date: Jan. 7, 2021

(54) GROUP-III NITRIDE LAMINATE

(71) Applicants: SCIOCS COMPANY LIMITED, Hitachi-shi (JP); SUMITOMO CHEMICAL COMPANY, LIMITED, Tokyo (JP)

(72) Inventors: Ryota ISONO, Hitachi-shi (JP); Takeshi TANAKA, Hitachi-shi (JP)

(73) Assignees: SCIOCS COMPANY LIMITED, Hitachi-shi (JP); SUMITOMO CHEMICAL COMPANY, LIMITED, Tokyo (JP)

(21) Appl. No.: 16/906,270

(22) Filed: Jun. 19, 2020

(30) Foreign Application Priority Data
Jun. 24, 2019 (JP) 2019-116392

(51) Int. Cl. H01L 29/20; H01L 29/205; H01L 29/778

(52) U.S. Cl. CPC H01L 29/2003; H01L 29/7786; H01L 29/205

(57) ABSTRACT

There is provided a group III nitride laminate, including:
a substrate comprised of silicon carbide; a first layer comprised of aluminum nitride and formed on the substrate; a second layer comprised of gallium nitride and formed on the first layer; and a third layer formed on the second layer and comprised of group III nitride having an electron affinity lower than that of the gallium nitride comprised in the second layer, the second layer containing silicon at an average concentration of less than 1×10¹⁶/cm³ in a lower layer portion when the second layer is divided into three equal thicknesses.

### BACKGROUND

### Technical Field

The present disclosure relates to a group III nitride laminate.

### Description of Related Art

An epitaxial substrate with group III nitride layers grown on a silicon carbide substrate has been developed. Such an epitaxial substrate is included in a semiconductor device such as a high electron mobility transistor (HEMT) as a material for manufacturing the same (see Patent Document 1).

In the HEMT including such an epitaxial substrate, it is desired to suppress leak current.

### [Patent Document 1] Japanese Patent Laid Open Publication No. 2018-200934

### SUMMARY

An object of the present disclosure is to provide a technique of suppressing both leak current and current collapse in HEMT including an epitaxial substrate with group III nitride layers grown on a silicon carbide substrate.

According to an aspect of the present disclosure, there is provided a group III nitride laminate, including:

a substrate comprised of silicon carbide:

a first layer comprised of aluminum nitride and formed on the substrate;

a second layer comprised of gallium nitride and formed on the first layer; and

a third layer formed on the second layer and comprised of group III nitride having an electron affinity lower than that of the gallium nitride comprised in the second layer,

the second layer containing silicon at an average concentration of less than 1×10¹⁶/cm³ in a lower layer portion when the second layer is divided into three equal thicknesses.

According to another aspect of the present disclosure, there is provided a group III nitride laminate, including:

a substrate comprised of silicon carbide:

a first layer comprised of aluminum nitride and formed on the substrate;

a second layer comprised of gallium nitride and formed on the first layer; and

a third layer formed on the second layer and comprised of group III nitride having an electron affinity lower than that of the gallium nitride comprised in the second layer,

the second layer containing oxygen at an average concentration of less than 1×10¹⁶/cm³ in a lower layer portion when the second layer is divided into three equal thicknesses.

There is provided a technique of suppressing leak current in HEMT including an epitaxial substrate with group III nitride layers grown on a silicon carbide substrate.

### BRIEF DESCRIPTION OF THE DRAWINGS

FIG. 1A and FIG. 1B are schematic cross-sectional views illustrating a group III nitride laminate according to an embodiment of the present disclosure, wherein FIG. 1A illustrates a group III nitride laminate in the form of an epitaxial substrate and FIG. 1B illustrates a group III nitride laminate in the form of HEMT.

FIG. 2 is a SIMS profile of Si concentration in an epi layer obtained by an experimental example.

FIG. 3 is a SIMS profile of O concentration in the epi layer obtained by an experimental example.

FIG. 4A is a schematic view conceptually illustrating a MOVPE apparatus used for manufacturing an epitaxial substrate included in the group III nitride laminate according to an embodiment, and FIG. 4B is a schematic timing chart illustrating a growth step of the epi layer included in the group III nitride laminate according to an embodiment.

### DETAILED DESCRIPTION OF THE DISCLOSURE

### An Embodiment of the Present Disclosure

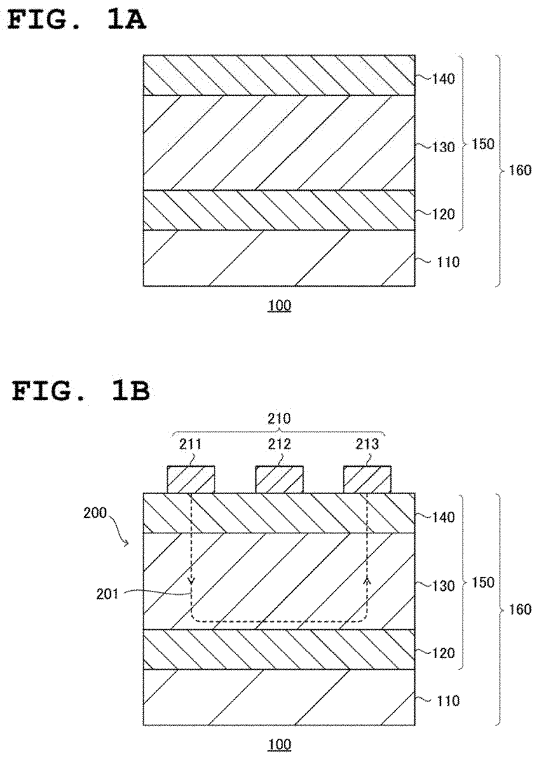

A group III nitride laminate 100 (also referred to as a laminate 100 hereafter) according to an embodiment of the present disclosure will be described. FIG. 1A and FIG. 1B are schematic cross-sectional views illustrating a laminate 100. The laminate 100 includes a substrate 110 and a group III nitride layer 150 (also referred to as an epi layer 150 hereafter) comprised of group III nitride and formed on the substrate 110. The epi layer 150 includes a nucleation layer 120, a buffer/channel layer 130, and a barrier layer 140.

As will be described in detail later, one of the features of the laminate 100 according to the present embodiment, leak current is suppressed by suppressing at least one of a silicon concentration and an oxygen concentration in a lower portion of the buffer/channel layer 130.

The laminate 100 may be, for example, in the form of an epitaxial substrate 160 (also referred to as an epi substrate 160 hereafter) including the substrate 110 and the epi layer 150. FIG. 1A illustrates the laminate 100 in the form of the epi substrate 160. Also, the laminate 100 may be, for example, in the form of a semiconductor device including the epi substrate 160 as a material, more specifically, in the form of a high electron mobility transistor (HEMT) 200 including an electrode 210 (source electrode 211, gate electrode 212, and drain electrode 213) on an upper side of the epi layer 150 (on an upper side of the barrier layer 140). FIG. 1B illustrates the laminate 100 in the form of the HEMT 200. The laminate 100 in the form of the HEMT 200 may also be in the form of a wafer or in the form of chips obtained by dividing the wafer.

Hereinafter, a configuration of the laminate 100 in the form of the HEMT 200 will be exemplarily described, with reference to FIG. 1B. The substrate 110 is comprised of silicon carbide (SiC), and is a base substrate for heteroepitaxially growing the epi layer 150 thereon. As SiC comprised in the substrate 110, for example, polytype 4H or polytype 6H semi-insulating SiC is used. Here, “semi-insulating” means, for example, a state where a specific resistance is 10⁵ Ωcm or more. The surface of the substrate 110, which is a base substrate for growing the epi layer 150 thereon, is formed as, for example, (0001) plane (a silicon surface of c-plane).

The nucleation layer 120 is formed on the substrate 110 (directly on the substrate 110). The nucleation layer 120 is comprised of aluminum nitride (AlN), and functions as a nucleation layer that generates nuclei for crystal growth of the buffer/channel layer 130. Preferably, the nucleation layer 120 has a thickness of, for example, 1 nm or more and 200 nm or less (preferably 5 nm or more and 30 nm or less). The nucleation layer 120 is preferably not excessively thin in order to suppress leak current, and is preferably not excessively thick in order to suppress generation of pits.

The buffer/channel layer 130 (also referred to as a channel layer 130 hereafter) is formed on the nucleation layer 120 (directly on the nucleation layer 120). The channel layer 130 is comprised of gallium nitride (GaN). A lower side portion of the channel layer 130 functions as a buffer layer for improving crystallinity of an upper side portion of the channel layer 130. Further, the upper side portion of the channel layer 130 functions as a channel layer through which electrons travel during operation of the HEMT 200. The channel layer (buffer/channel layer) 130 has a thickness of, for example, 100 nm or more and 1300 nm or less. The channel layer 130 is preferably not excessively thin in order to suppress generation of pits, and is preferably not excessively thick in order to keep a cost down.

The barrier layer 140 is formed on the channel layer 130. The barrier layer 140 is comprised of group III nitride having an electron affinity lower than that of GaN which is comprised in the channel layer 130, such as aluminum gallium nitride (AlGaN) containing aluminum (Al) and gallium (Ga) as group III elements. The barrier layer 140 induces a two-dimensional electron gas (2DEG) in the channel layer 130, and functions as a barrier layer for spatially confining the 2DEG inside the channel layer 130. Preferably, the barrier layer 140 has a thickness of, for example, 1 nm or more and 50 nm or less (preferably 10 nm or more and 50 nm or less). Al composition of AlGaN comprised in the barrier layer 140 is, for example, 0.1 or more and 0.5 or less. When the barrier layer 140 has high Al composition and thick, crystals comprised in the barrier layer 140 are easily broken, and when the barrier layer 140 has low Al composition and is thin, properties of the barrier layer 140 are likely to deteriorate. Therefore, it is preferable to form the barrier layer 140 to have low Al composition and thick, or to have high Al composition and have a film thickness not allowing the crystallinity to be broken.

Note that a cap layer 150 may be formed on the barrier layer 140, if necessary. That is, the epi layer 150 may include the cap layer 150, if necessary. The cap layer 150 is comprised of, for example, GaN, and in order to improve a device characteristics (controllability of a threshold voltage, etc.) of the HEMT 200, the cap layer 150 is interposed between the barrier layer 140 and the gate electrode 212.

On the epi layer 150 (above the barrier layer 140), a source electrode 211, a gate electrode 212, and a drain electrode 213 are formed as the electrode 210 of the HEMT 200. The gate electrode 212 is comprised of, for example, a Ni/Au layer which is a laminate of a nickel (Ni) layer and a gold (Au) layer. When the laminate is described as X/Y, it means that the laminating is carried out in an order of X and Y, in this specification.

Each of the source electrode 211 and the drain electrode 213 is comprised of, for example, a Ti/Al layer which is a laminate of a titanium (Ti) layer and an Al layer. Each of the source electrode 211 and the drain electrode 213 may be comprised by laminating a Ni/Au layer on the Ti/Al layer.

A flow of the leak current (electron movement direction) in the channel layer (buffer/channel layer) 130 is schematically indicated by a dashed arrow 201 when a voltage is applied between the source electrode 211 and the drain electrode 213 of the HEMT 200.

The present inventors examined a difference between the epi layer 150 according to the present embodiment having a small leak current (also referred to as the epi layer 150 of the example hereafter), and the epi layer 150 according to the comparative embodiment having a large leak current (also referred to as the epi layer 150 of the comparative example hereafter), by preparing the HEMT 200 under variously changed growth conditions of the epi layer 150 as an experimental example. As a result, the following findings were obtained regarding a secondary ion mass spectrometry (SIMS) profile (depth direction distribution) of an impurity concentration in the channel layer 130.

The leak current in the HEMT 200 having the epilayer 150 of the example is preferably less than 1×10⁻⁶ A, more preferably less than 1×10⁻⁷ A. In contrast, the leak current in the HEMT 200 having the epi layer 150 of the comparative example is 1×10⁻⁶ A or more, for example, about 1×10⁻⁵ A. An example of the leak current is an off-leak current. The off-leak current can be measured by applying a sufficient negative voltage to the gate electrode 212 in the prepared HEMT 200 to pinch off the element and turn it off, and thereafter applying a voltage of, for example, about 50 V between the source electrode 211 and the drain electrode 213. Note that the inter-element leak current can be decreased by decreasing the off-leak current. The inter-element leak current can be measured in such a way that each element on the wafer is separated by ion implantation or ICP etching, etc., and thereafter a voltage of about 50 V is applied between ohmic electrodes of adjacent elements.

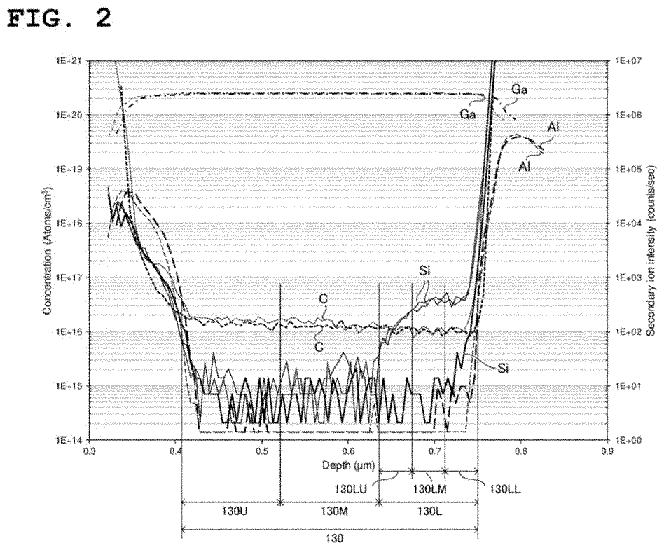

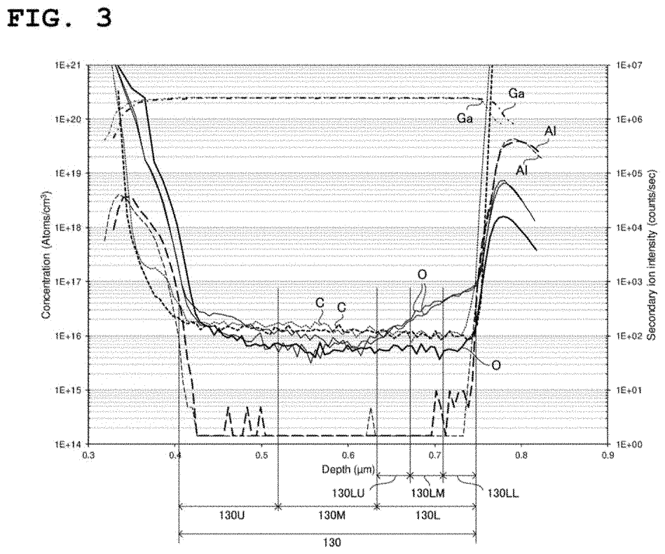

The findings will be described with reference to FIGS. 2 and 3. Examples of the impurity concentration in the channel layer 130 include a silicon concentration, an oxygen concentration, and a carbon concentration. FIG. 2 is a SIMS profile of the silicon (Si) concentration in the epi layer 150 (nucleation layer 120, channel layer 130 and barrier layer 140) obtained by the experimental example. FIG. 3 is a SIMS profile of the oxygen (O) concentration in the epi layer 150 obtained by the experimental example. The SIMS profile may be simply referred to as a profile hereafter.

FIG. 2 and FIG. 3 also illustrate profiles of an aluminum (Al) concentration, a gallium (Ga) concentration, and a carbon (C) concentration. The profiles of the aluminum concentration, the Ga concentration, and the C concentration are common in FIG. 2 and FIG. 3.

FIG. 2 and FIG. 3 will be described as follows. For Si, O and C, a left-side axis (Concentration (Atoms/cm³)) indicates the concentration (as a direct numerical value of the concentration). For Al and Ga, a right-side axis (Secondary ion intensity (counts/sec)) indicates the concentration as a SIMS count corresponding to the concentration.

The Si concentration profile is indicated by a solid line in FIG. 2 and the O concentration profile is indicated by a solid line in FIG. 3. In FIG. 2 and FIG. 3, the aluminum concentration profile is indicated by a broken line, the Ga concentration profile is indicated by a one-dot chain line, and the C concentration profile is indicated by a dotted line. The profile of the epi layer 150 of the example is indicated by a thick line, and the profile of the epi layer 150 of the comparative example is indicated by a thin line. The Si concentration profile and the O concentration profile of the comparative example show the results (two lines) for two samples, respectively.

The channel layer (buffer/channel layer) 130 is defined as a region located directly on the nucleation layer 120, which is the region where the aluminum concentration is decreased to 1/1000 or less (4×10² counts/sec or less in the examples of FIGS. 2 and 3) of a peak concentration in the nucleation layer 120 (4×10⁵ counts/sec in the examples of FIGS. 2 and 3). That is, a lower end of the channel layer 130 is defined as a depth position at which the Al concentration reaches 1/1000 of a peak concentration in the nucleation layer 120, falling from the nucleation layer 120 toward the channel layer 130, the nucleation layer 120 being formed directly under the channel layer 130 and comprised of AlN. Also, an upper end of the channel layer 130 is defined as a depth position at which the Al concentration reaches the same concentration as the concentration defining the lower end of the channel layer 130, rising from the channel layer 130 toward the barrier layer 140 formed directly on the channel layer 130 and comprised of AlGaN.

From the lower end of the channel layer 130, a lower layer portion 130L, a middle layer portion 130M, and an upper layer portion 130U of the channel layer 130 are defined for each portion having a thickness of ⅓ of the channel layer 130. Also, from the lower end of the lower layer portion 130L of the channel layer 130 (that is, the lower end of the channel layer 130), a lower layer portion 130LL, a middle layer portion 130LM, and an upper layer portion 130LU of the lower layer portion 130L are defined for each portion having a thickness of ⅓ of the lower layer portion 130L. That is, the lower layer portion 130L of the channel layer 130 is a lower layer portion when the channel layer 130 is divided into three equal thicknesses. Also, the middle layer portion 130LM of the lower layer portion 130L is a middle layer portion (in the divided lower layer portion L) when the lower layer portion 130L is divided into three equal thicknesses.

The region where the Al concentration is 1/1000 or less of the peak concentration in the nucleation layer 120, that is, a thickness range of the channel layer 130 are not exactly the same between the example and the comparative example, but they are almost the same. FIG. 2 and FIG. 3 illustrate the thickness range of the channel layer 130 of the example.

The nucleation layer 120 is arranged in the lower part and the lower end of the channel layer 130, that is, to the right of the channel layer 130 in FIGS. 2 and 3. Further, the barrier layer 140 is arranged on the upper end of the channel layer 130, that is, to the left of the channel layer 130 in FIG. 2 and FIG. 3.

Regarding the Al concentration profile and the Ga concentration profile, there is no significant difference between the example and the comparative example. The depth position where the Al concentration has a peak in the nucleation layer 120 is also referred to as an Al peak depth position hereafter.

Regarding the Si concentration profile, a great difference is observed between the example and the comparative example. The difference between the example and the comparative example is particularly remarkable in the lower layer portion 130L of the channel layer 130. In both the example and the comparative example, the Si concentration has a height of 1×10²¹/cm³ or more at the Al peak depth position of the nucleation layer 120. The reason can be considered that a substrate 110 which is comprised of SiC exists directly under the thin nucleation layer 120. Also, in both the example and the comparative example, the Si concentration decreases from the nucleation layer 120 toward the channel layer 130, and is decreased to less than 1×10¹⁷/cm³ near the lower end of the channel layer 130 (within the lower layer portion 130LL).

The Si concentration of the comparative example keeps a height of 1×10¹⁶/cm³ or more in the lower layer portion 130LL and the middle layer portion 130LM of the lower layer portion 130L of the channel layer 130, and decreases to less than 1×10¹⁶/cm³ in the upper layer portion 130LU of the lower layer portion 130L.

In contrast, the Si concentration of the example decreases to less than 1×10¹⁶/cm³ in the lower layer portion 130LL of the lower end portion 130L of the channel layer 130, and keeps a lowness of less than 1×10¹⁶/cm³, or generally less than 1×10¹⁵/cm³ (maximum of about 2×10¹⁵/cm³) in the middle layer portion 130LM and the upper layer portion 130LU of the lower layer portion 130L.

In both the example and the comparative example, the Si concentration keeps a lowness of less than 1×10¹⁶/cm³ in a thickness range of the middle layer portion 130M and up to the vicinity of the upper end of the upper end portion 130U. The Si concentration of the example is slightly lower than the Si concentration of the comparative example and keeps a lowness of less than about 1×10¹⁵/cm³ (about 2×10¹⁵/cm³ at maximum) in the above thickness range. The Si concentration increases toward the barrier layer 140 upward to the vicinity of the upper end of the upper layer portion 130U of the channel layer 130.

As described above, it was found that a Si concentration distribution in the lower layer portion 130L of the channel layer 130 is significantly different between the example and the comparative example. An average Si concentration in the lower layer portion 130L is defined, for example, by an average concentration in the middle layer portion 130LM of the lower layer portion 130L, where there is little sudden concentration change. The average Si concentration in the lower layer portion 130L of the channel layer 130 is 1×10¹⁶/cm³ or more in the comparative example, whereas it is less than 1×10¹⁶/cm³ in the example, and preferably less than 1×10¹⁵/cm³.

Regarding an O concentration profile, as in the case of the Si concentration profile, a great difference is observed between the example and the comparative example, and the difference between the example and the comparative example is particularly remarkable in the lower layer portion 130L of the channel layer 130.

The O concentration of the comparative example shows a height of about 1×10¹⁶/cm³ or more in the lower layer portion 130L of the channel layer 130 and tends to decrease toward the middle layer portion 130M of the channel layer 130. The O concentration of the comparative example shows a lowness of less than 1×10¹⁶/cm³ in the middle layer portion 130M of the channel layer 130 and thereafter tends to increase toward the barrier layer 140 in the upper layer portion 130U of the channel layer 130.

In contrast, the O concentration of the example shows generally a lowness of less than 1×10¹⁶/cm³ in the lower layer portion 130L and the middle layer portion 130M of the channel layer 130. Similarly to the O concentration of the comparative example, the O concentration of the example tends to increase toward the barrier layer 140 in the upper layer portion 130U of the channel layer 130.

As described above, it was found that the O concentration distribution in the lower layer portion 130L of the channel layer 130 was remarkably different between the example and the comparative example. Similarly to the average Si concentration in the lower layer portion 130L, the average O concentration in the lower layer portion 130L is defined, for example, by the average concentration in the middle layer portion 130LM of the lower layer portion 130L. The average O concentration in the lower layer portion 130L of the channel layer 130 is 1×10¹⁶/cm³ or more in the comparative example, whereas it is less than 1×10¹⁶/cm³ in the example.

Regarding the C concentration profile, there is no significant difference between the example and the comparative example. The C concentration shows a height of 1×10²¹/cm³ or more at the Al peak depth position of the nucleation layer 120. The reason can be considered that the substrate 110 comprised of SiC exists directly under the thin nucleation layer 120. The C concentration decreases from the nucleation layer 120 toward the channel layer 130, and decreases to about 1×10¹⁶/cm³ in the vicinity of the lower end in the channel layer 130. The C concentration is generally about 1 to 2×10¹⁶/cm³ in a total thickness range of the channel layer 130, and tends to increase in the barrier layer 140.

Similarly to the average Si concentration or the average O concentration in the lower layer portion 130L of the channel layer 130, the average C concentration in the lower layer portion 130L of the channel layer 130 is defined, for example, by the average concentration in the middle layer portion 130LM of the lower layer portion 130L. In the example, the average Si concentration and the average O concentration in the lower layer portion 130L of the channel layer 130 are respectively lower than the average C concentration in the lower layer portion 130L of the channel layer 130. Further, in the example, preferably, the (non-average) Si and O concentrations are each characterized by being lower than the C concentration in the total thickness range of the middle layer portion 130LM of the lower layer portion 130L of the channel layer 130.

The epi layer 150 including the channel layer 130 grows by, for example, metal organic chemical vapor deposition (MOVPE) as described later. During the above growth, inclusion of C derived from the organic raw material occurs in the channel layer 130 and the like. The concentration of C contained in the channel layer 130 (an average C concentration in the lower layer portion 130L) is controlled by growth conditions, so as not to be too high, for example, to be less than 1×10¹⁷/cm³.

As described above, the SIMS profiles of various impurities obtained by the experimental example were examined, and the present inventors found that the Si concentration distribution and the O concentration distribution in the lower layer portion 130L of the channel layer 130 are remarkably different from those of the comparative example, more specifically, the Si concentration and the O concentration are remarkably decreased in the lower layer portion 130L.

Although a mechanism of decreasing the leak current in the example is not clear, it is estimated that at least one of the decrease of the Si concentration and the decrease of the O concentration in the example may contribute to the decrease of the leak current, because such a significant decrease of the Si concentration and a significant decrease of the O concentration are observed in the SIMS profile.

In the experimental example, the growth conditions of the epi layer 150 were variously changed. As a result, as will be described later in detail, it was found that the epi layer 150 of the example can be formed by a production method that suppresses inclusion of Al into the channel layer 130, Al being derived from the formation of the nucleation layer 120 comprised of AlN.

A relationship between the suppression of the inclusion of Al into the channel layer 130 and the decrease of the Si concentration and the O concentration in the lower layer portion 130L of the channel layer 130 is not clear. However, as one of the considerations, it can be considered that Si and O are hardly taken into the channel layer 130 because a growth mode of the GaN crystal changes in the initial growth stage of the channel layer 130 due to suppressing the inclusion of Al. Since an inclusion amount of Al into the channel layer 130 is extremely small, it is considered that the difference in the inclusion of Al into the channel layer 130 between the example and the comparative example is not so clearly reflected in the SIMS profile.

A method for manufacturing the laminate 100 according to the present embodiment will be described next. Here, the method for manufacturing the laminate 100 in the form of the HEMT 200 will be shown. A method for manufacturing the epi substrate 160 will be described first. A SiC substrate is prepared as the substrate 110. The epi substrate 160 is formed by growing the nucleation layer 120, the channel layer 130, and the barrier layer 140, which are the layers included in the epi layer 150, on or above the substrate 110 by, for example, MOVPE.

For example, a trimethylaluminum (Al(CH₃)₃, TMA) gas is used as an Al source gas out of the group III source gases. For example, a trimethylgallium (Ga(CH₃)₃, TMG) gas is used as a Ga source gas out of the group III source gases. For example, ammonia (NH₃) is used as a nitrogen (N) source gas, which is a group V source gas. For example, at least one of a nitrogen gas (N₂ gas) and a hydrogen gas (H₂ gas) is used as a carrier gas. Further, for example, an ammonia gas or a chlorine gas is used as a cleaning gas to perform cleaning described later. A growth temperature can be selected in a range of 900° C. to 1400° C., and a V/III ratio, which is a flow rate ratio of the group V source gas to the group III source gas, can be selected, for example, in a range of 10 to 5000. A ratio of a supply amount of each source gas is adjusted according to a composition of each layer to be formed. The thickness of each layer to be formed can be controlled by growth time, for example, by calculating the growth time corresponding to a designed thickness, from a growth rate obtained in a preliminary experiment.

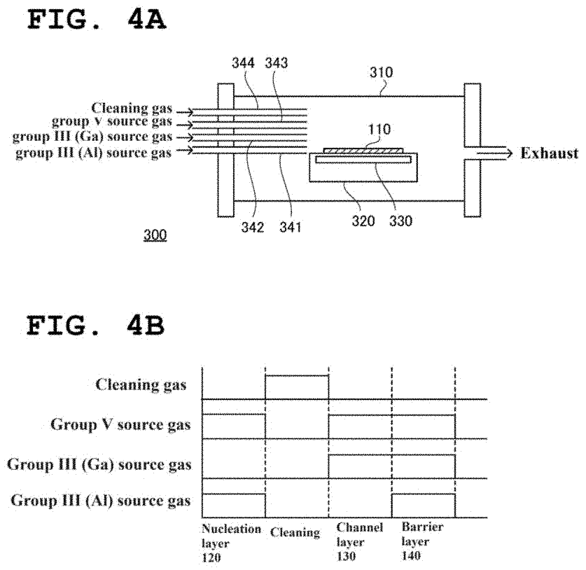

A method for suppressing the inclusion of Al into the channel layer 130 will be exemplarily described hereafter. FIG. 4A is a schematic view conceptually illustrating a MOVPE apparatus 300 used for manufacturing the epi substrate 160 according to the present embodiment. A susceptor 320 for mounting the substrate 110 is installed in a reaction furnace 310 of the MOVPE apparatus 300. A heater 330 for heating the substrate 110 to a predetermined temperature is installed on a lower side of a mounting surface of the susceptor 320. Gas pipes 341, 342, 343, and 344 for supplying various gases toward the substrate 110 are introduced into the reaction furnace 310.

The gas pipe 341 supplies an Al raw material (for example, TMA) out of group III raw materials. The gas pipe 342 supplies a group III raw material other than the Al raw material, here, a Ga raw material (for example, TMG). The gas pipe 343 supplies a group V raw material (for example, NH₃). The gas pipe 344 supplies a cleaning gas to perform cleaning for removing the Al raw material adhered to a furnace wall, etc., of the reaction furnace 310.

FIG. 4B is a schematic timing chart illustrating the growth step of the epi layer 150 according to the present embodiment. In the step of forming the nucleation layer 120, the nucleation layer 120 is formed by supplying the Al source gas and the N source gas toward the substrate 110 to grow AlN. Due to the formation of the nucleation layer 120, the Al raw material adheres to the furnace wall, etc., of the reaction furnace 310.

In the cleaning step following the step of forming the nucleation layer 120, the Al raw material adhered to the furnace wall, etc., of the reaction furnace 310 is removed by supplying a cleaning gas into the reaction furnace 310. When using a chlorine gas for cleaning, the cleaning step is performed in a state where the substrate 110 with the nucleation layer 120 formed thereon is taken out of the reaction furnace 310 once. The reason is that the nucleation layer 120 is prevented from being etched in the cleaning step. When using an ammonia gas for cleaning, the substrate 110 does not have to be taken out of the reaction furnace 310. It is more preferable to remove the Al raw material adhered to the inner wall of the gas pipe 341 by flowing the cleaning gas (for example, the ammonia gas or the chlorine gas) in the cleaning step, through the gas pipe 341 used for supplying the Al raw material in the step of forming the nucleation layer 120.

In the step of forming the channel layer 130 following the cleaning step, the channel layer 130 is formed by supplying the Ga source gas and the N source gas toward the substrate 110 to grow GaN. According to the present embodiment, the cleaning step is performed prior to the step of forming the channel layer 130 to remove the Al raw material adhered to the furnace wall, etc., of the reaction furnace 310, thereby suppressing the inclusion of Al during formation of the channel layer 130.

Further, according to the present embodiment, the gas pipe 341 for supplying the Al raw material gas and the gas pipe 342 for supplying the Ga raw material gas are separated. Thereby, the Al source gas remaining in the gas pipe can be further prevented from being supplied together with the Ga source gas, which occurs in a mode in which the Al source gas and the Ga source gas are supplied from a common gas pipe, and therefore the inclusion of Al in the channel layer 130 can be further suppressed.

According to the present embodiment, as described above, the epi layer 150 with suppressed Si concentration and O concentration in the lower portion 130L of the channel layer 130, can be formed by suppressing the inclusion of Al into the channel layer 130 due to the formation of the nucleation layer 120. In the cleaning step, various conditions such as a flow rate of the cleaning gas and a length of time for performing the cleaning step can be determined by preliminary experiments in order that the Si concentration and the O concentration in the lower layer portion 130L of the channel layer 130 are suppressed to predetermined concentrations.

In the step of forming the barrier layer 140 following the step of forming the channel layer 130, the barrier layer 140 is formed by supplying the Al source gas, the Ga source gas, and the N source gas toward the substrate 110 to grow AlGaN. As described above, the epi substrate 160 is manufactured by growing the epi layer 150 on the substrate 110.

A method for manufacturing the HEMT 200 will be described next. After manufacturing the epi substrate 160, the HEMT 200 is manufactured by forming electrodes 210 (source electrode 211, gate electrode 212 and drain electrode 213) on the epi layer 150. When manufacturing the HEMT 200, other members such as a protective film may be formed, if necessary. The electrodes 210, the protective film, etc., may be formed by a known method. As described above, the laminate 100 according to the present embodiment is manufactured.

As described above, according to the present embodiment, with at least one of the Si concentration and the O concentration suppressed in the lower layer portion 130L of the buffer layer (buffer/channel layer) 130, the leak current in the laminate 100 can be suppressed.

### <Preferable Aspects of the Present Disclosure>

Preferable aspects of the present disclosure will be additionally described hereafter.

### (Supplementary Description 1)

There is provided a group III nitride laminate, including:

a substrate comprised of silicon carbide;

a first layer comprised of aluminum nitride and formed on the substrate (directly on the substrate);

a second layer comprised of gallium nitride and formed on the first layer (directly on the first layer); and

a third layer formed on the second layer and comprised of group III nitride (Group III nitride containing aluminum, aluminum gallium nitride) having an electron affinity lower than that of the gallium nitride comprised in the second layer,

the second layer containing silicon at an average concentration of less than 1×10¹⁶/cm³ in a lower layer portion when the second layer is divided into three equal thicknesses.

### (Supplementary Description 2)

There is provided the Group III nitride laminate according to the supplementary description 1, wherein the second layer has an average silicon concentration of less than 1×10¹⁵/cm³ in the lower layer portion of the second layer.

### (Supplementary Description 3)

There is provided the group III nitride laminate according to the supplementary description 1 or 2, wherein the second layer has an average oxygen concentration of less than 1×10¹⁶/cm³ in the lower layer portion of the second layer.

### (Supplementary Description 4)

There is provided the group III nitride laminate according to the any one of the supplementary descriptions 1 to 3, wherein the average silicon concentration in the lower layer portion of the second layer is lower than the average carbon concentration in the lower layer portion of the second layer.

### (Supplementary Description 5)

There is provided the group III nitride laminate according to the any one of the supplementary descriptions 1 to 4, wherein the average oxygen concentration in the lower layer portion of the second layer is lower than the average carbon concentration in the lower layer portion of the second layer.

### (Supplementary Description 6)

There is provided the Group III nitride laminate according to the supplementary description 4 or 5, wherein the second layer has an average carbon concentration of less than 1×10¹⁷/cm³ in its lower layer portion.

### (Supplementary Description 7)

There is provided a group III nitride laminate, including:

a substrate comprised of silicon carbide;

a first layer comprised of aluminum nitride and formed on the substrate (directly on the substrate);

a second layer comprised of gallium nitride and formed on the first layer (directly on the first layer); and

a third layer formed on the second layer and comprised of group III nitride (Group III nitride containing aluminum, aluminum gallium nitride) having an electron affinity lower than that of the gallium nitride comprised in the second layer,

the second layer containing oxygen at an average concentration of less than 1×10¹⁶/cm³ in a lower layer portion when the second layer is divided into three equal thicknesses.

### (Supplementary Description 8)

There is provided the Group III nitride laminate according to any one of the supplementary descriptions 1 to 7, having a silicon concentration of 1×10²¹/cm³ or more at a depth position where the aluminum concentration of the first layer shows a peak.

### (Supplementary Description 9)

There is provided the group III nitride laminate according to any one of the supplementary descriptions 1 to 8, having a carbon concentration of 1×10²¹/cm³ or more at a depth position where the aluminum concentration of the first layer shows a peak.

### (Supplementary Description 10)

There is provided the group III nitride laminate according to any one of the supplementary descriptions 1 to 9, having electrodes arranged on or above the third layer, and used as a high electron mobility transistor.

### (Supplementary Description 11)

There is provided the group III nitride laminate according to the supplementary description 10, wherein a leak current (off-leak current) in the high electron mobility transistor is preferably less than 1×10⁻⁶ A, more preferably less than 1×10⁻⁷ A, the leak current being measured by applying a negative voltage to a gate electrode of the high electron mobility transistor to turn it off, and thereafter applying a voltage of 50 V between a source electrode and a drain electrode.

### (Supplementary Description 12)

There is provided the group III nitride laminate according to any one of the supplementary descriptions 1 to 11, wherein the second layer is defined as a region where the Aluminum concentration is decreased to 1/1000 or less with respect to the peak concentration of the aluminum concentration in the first layer (shown as SIMS count).

### (Supplementary Description 13)

There is provided the group III nitride laminate according to any one of the supplementary descriptions 1 to 12, wherein the average silicon concentration, the average oxygen concentration, or the average carbon concentration in the lower layer portion of the second layer is defined as an average density in a middle layer portion of the divided lower layer portion when the lower layer portion is divided into three equal thicknesses.

What is claimed is:

1. A group III nitride laminate, comprising:
a substrate comprised of silicon carbide;
a first layer comprised of aluminum nitride and formed on the substrate;
a second layer comprised of gallium nitride and formed on the first layer; and
a third layer formed on the second layer and comprised of group III nitride having an electron affinity lower than that of the gallium nitride comprised in the second layer,
the second layer containing silicon at an average concentration of less than 1×10¹⁶/cm³ in a lower layer portion when the second layer is divided into three equal thicknesses.

2. The group III nitride laminate according to claim 1, wherein the second layer has an average silicon concentration of less than 1×10¹⁵/cm³ in the lower layer portion of the second layer.

3. The group III nitride laminate according to claim 1, wherein the second layer has an average oxygen concentration of less than 1×10¹⁶/cm³ in the lower layer portion of the second layer.

4. The group III nitride laminate according to claim 1, wherein the average silicon concentration in the lower layer portion of the second layer is lower than the average carbon concentration in the lower layer portion of the second layer.

5. The group III nitride laminate according to claim 1, wherein the average oxygen concentration in the lower layer portion of the second layer is lower than the average carbon concentration in the lower layer portion of the second layer.

6. A group III nitride laminate, comprising:
a substrate comprised of silicon carbide;
a first layer comprised of aluminum nitride and formed on the substrate;
a second layer comprised of gallium nitride and formed on the first layer; and
a third layer formed on the second layer and comprised of group III nitride having an electron affinity lower than that of the gallium nitride comprised in the second layer,
the second layer containing oxygen at an average concentration of less than 1×10¹⁶/cm³ in a lower layer portion when the second layer is divided into three equal thicknesses.

7. The group III nitride laminate according to claim 1, having a silicon concentration of 1×10²¹/cm³ or more at a depth position where the aluminum concentration of the first layer shows a peak.

8. The group III nitride laminate according to claim 6, having a silicon concentration of 1×10²¹/cm³ or more at a depth position where the aluminum concentration of the first layer shows a peak.

9. The group III nitride laminate according to claim 1, having a carbon concentration of 1×10²¹/cm³ or more at a depth position where the aluminum concentration of the first layer shows a peak.

10. The group III nitride laminate according to claim 6, having a carbon concentration of 1×10²¹/cm³ or more at a depth position where the aluminum concentration of the first layer shows a peak.
